(19) United States
(12) Patent Application Publication
(10) Pub. No.: US 2018/0130681 A1
(43) Pub. Date: May 10, 2018

(54) PROCESSING SYSTEM

(71) Applicant: Tokyo Electron Limited, Tokyo (JP)

(72) Inventors: Tamotsu Tanifuji, Miyagi (JP); Tamaki Yuasa, Yamanashi (JP); Satoru Kawakami, Yamanashi (JP)

(21) Appl. No.: 15/574,514

(22) PCT Filed: May 11, 2016
(86) PCT No.: PCT/JP2016/064066

§ 371 Date: Nov. 16, 2017

(30) Foreign Application Priority Data
May 21, 2015 (JP) 2015-103896

(51) Int. Cl. H01L 21/67; H01L 21/687; C23C 16/44; C23C 16/52; C23C 16/50; H01J 37/32

(52) U.S. Cl. CPC H01L 21/67173; H01L 21/67167; H01L 21/68707; H01L 21/67201; H01L 21/67017; H01L 21/67063; H01J 2237/334; C23C 16/52; C23C 16/50; H01J 37/32009; H01J 37/3244; H01J 2237/3321; C23C 16/4412

(57) ABSTRACT

A processing system includes: at least one processing unit. Each processing unit includes a plurality of processing chambers, and a utility module. Each of the processing chambers processes a processing target object using a supplied processing gas. The utility module includes a flow rate controller configured to control a flow rate of the processing gas supplied to each of the plurality of processing chambers. The plurality of processing chambers are disposed to overlap each other in a vertical direction. The utility module is disposed between two processing chambers adjacent in the vertical direction, among the plurality of processing chambers.

### TECHNICAL FIELD

Various aspects and exemplary embodiments of the present disclosure relate to a processing system.

### BACKGROUND

There is a case where a plurality of processing target substrates are processed in parallel using a plurality of substrate processing apparatuses in order to improve a throughput of a substrate processing. In this case, since the plurality of substrate processing apparatuses are disposed in a facility such as, for example, a clean room, an area occupied by the plurality of substrate processing apparatuses increases. Thus, a larger clean room becomes required and a facility cost is increased. In order to avoid this, it is considered the number of substrate processing apparatuses provided per unit area may be reduced by disposing the plurality of substrate processing apparatuses in the vertical direction in multi stages (see, e.g., Patent Document 1 below).

### PRIOR ART DOCUMENT

Patent Document
Patent Document 1: Japanese Patent Laid-Open Publication No. 2000-223425

### DISCLOSURE OF THE INVENTION

### Problems to be Solved

However, in the above described technology of Patent Document 1, since the plurality of substrate processing apparatuses are disposed in the vertical direction in multi stages, the number of substrate processing apparatuses provided per unit area is reduced, but an apparatus configured to supply, for example, a processing gas to each of the substrate processing apparatuses is disposed at a place separate from the substrate processing apparatuses. Thus, the occupied area in the entire system is still large.

### Means to Solve the Problems

According to an aspect of the present disclosure, for example, a processing system includes at least one processing unit. Each processing unit includes a plurality of processing chambers, and a utility module. Each of the processing chambers processes a processing target object using a supplied processing gas. The utility module includes a flow rate controller configured to control a flow rate of the processing gas supplied to each of the plurality of processing chambers. The plurality of processing chambers are disposed to overlap each other in a vertical direction. The utility module is disposed between two processing chambers adjacent in the vertical direction, among the plurality of processing chambers.

### Effect of the Invention

According to various aspects and exemplary embodiments of the present disclosure, the occupied area in the entire processing system may be reduced.

### EFFECT OF THE INVENTION

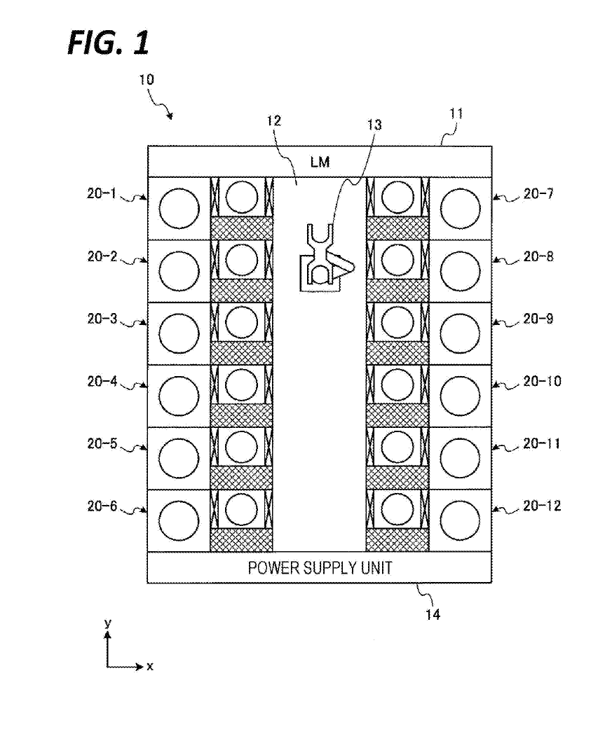

FIG. 1 is a view illustrating an example of a processing system.

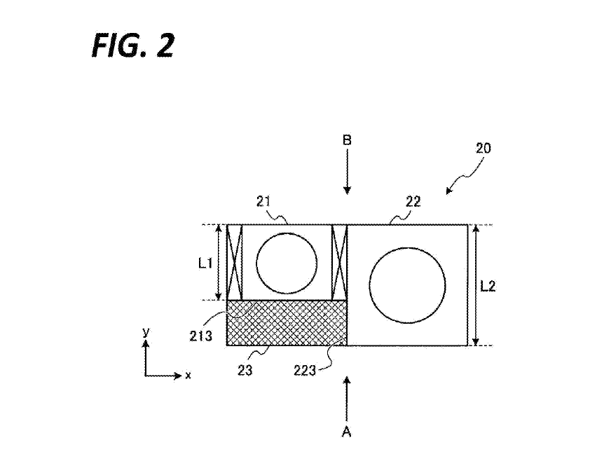

FIG. 2 is a view illustrating an example of a processing unit.

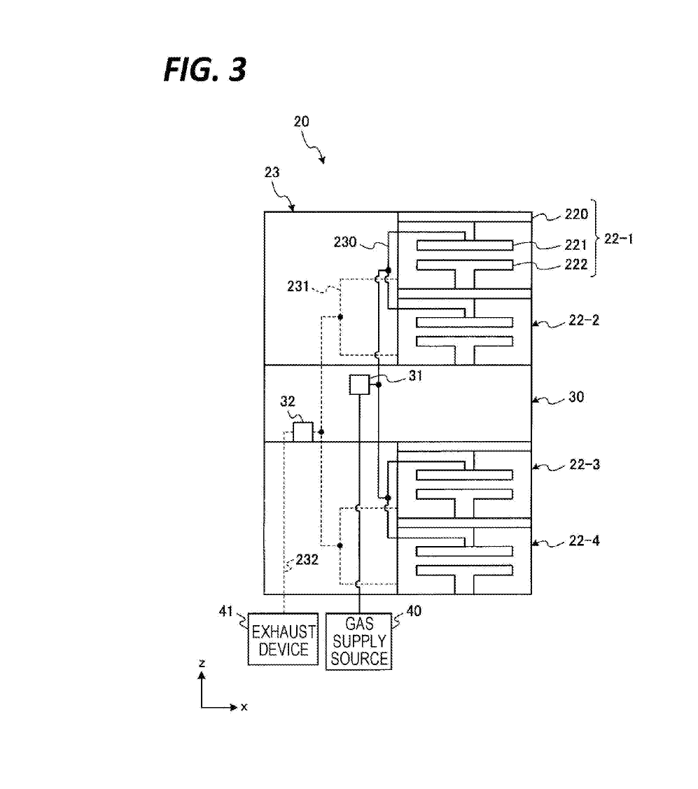

FIG. 3 is a view illustrating an example of the processing unit when viewed from the direction A in FIG. 2.

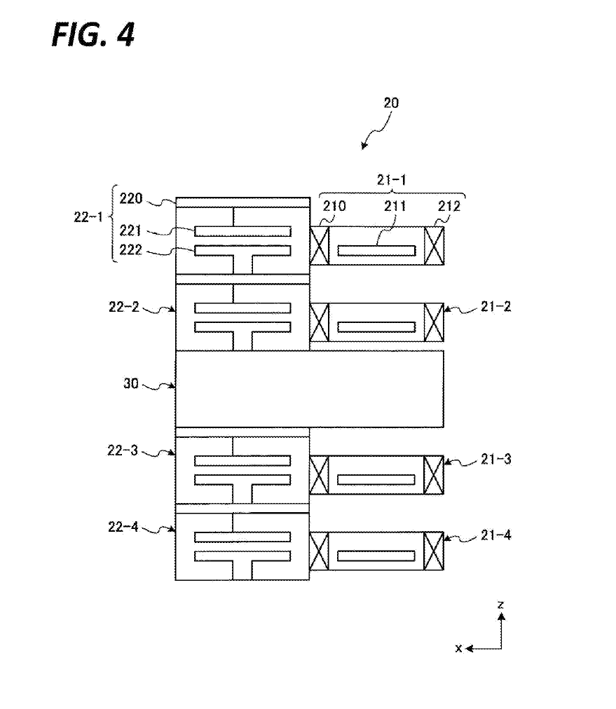

FIG. 4 is a view illustrating an example of the processing unit when viewed from the direction B in FIG. 2.

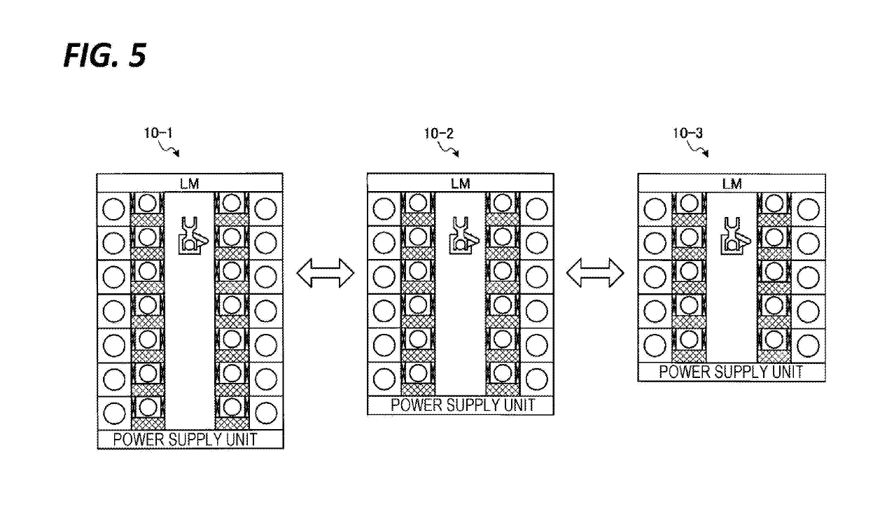

FIG. 5 is a view illustrating an example of the processing system when the number of processing units varies.

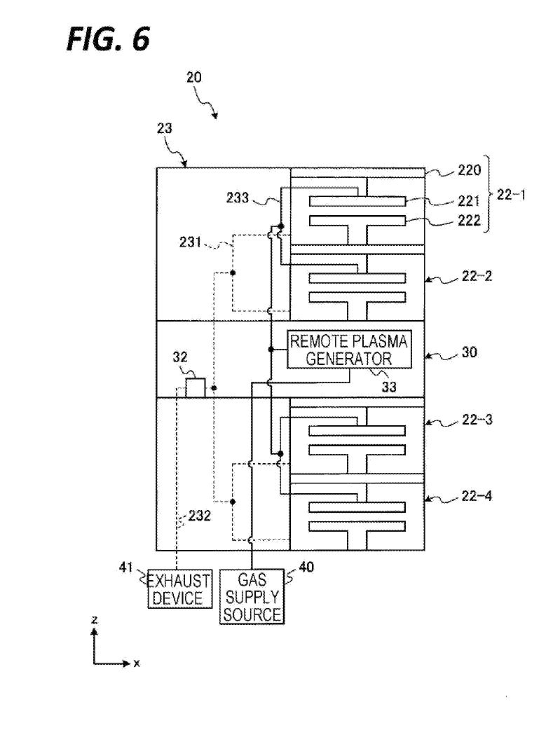

FIG. 6 is a view illustrating another example of the processing unit.

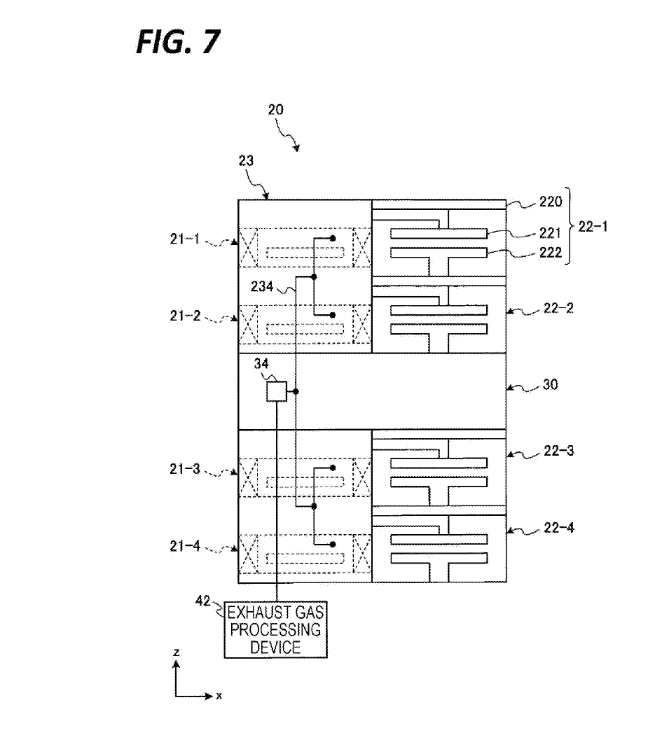

FIG. 7 is a view illustrating a further example of the processing unit.

### DETAILED DESCRIPTION TO EXECUTE THE INVENTION

The processing system according to an exemplary embodiment of the disclosure includes at least one processing unit. Each processing unit includes a plurality of processing chambers, and a utility module. Each of the processing chambers processes a processing target object using a supplied processing gas. The utility module includes a flow rate controller configured to control a flow rate of the processing gas supplied to each of the plurality of processing chambers. The plurality of processing chambers are disposed to overlap each other in a vertical direction. The utility module is disposed between two processing chambers adjacent in the vertical direction, among the plurality of processing chambers.

In the processing system according to an exemplary embodiment of the disclosure, each processing unit includes a first pipe through which the processing gas flows to be distributed from the flow rate controller to each of the plurality of processing chambers, and a length of the first pipe from the flow rate controller to each of the plurality of processing chambers may be same among the plurality of processing chambers within the processing unit.

In the processing system according to an exemplary embodiment of the disclosure, each processing unit includes a load lock module disposed adjacent to each of the processing chambers, for the processing chamber, a width of the load lock module in a direction from the load lock module toward the processing chamber is narrower than a width of the processing chamber disposed adjacent to the load lock module, and the first pipe is disposed in a gap formed by a side surface in an area not adjacent to the load lock module, in a side surface of the processing chamber at a side where the load lock module is disposed, and a side surface extending in a direction from the load lock module toward the processing chamber, among side surfaces of the load lock module.

In the processing system according to an exemplary embodiment of the disclosure, the utility module may further include an exhaust controller configured to control an exhaust amount of a gas exhausted from each of the plurality of processing chambers included in the processing unit.

In the processing system according to an exemplary embodiment of the disclosure, each processing unit includes a second pipe through which the gas exhausted from each of the plurality of processing chambers flows, and a length of the second pipe from each of the plurality of processing chambers to the exhaust controller may be same among the plurality of processing chambers within the processing unit.

In the processing system according to an exemplary embodiment of the disclosure, each processing unit includes a load lock module disposed adjacent to each of the processing chambers, for the processing chamber, a width of the load lock module in a direction from the load lock module toward the processing chamber is narrower than a width of the processing chamber disposed adjacent to the load lock module, and the second pipe may be disposed in a gap formed by a side surface in an area not adjacent to the load lock module, in a side surface of the processing chamber at a side where the load lock module is disposed, and a side surface extending in a direction from the load lock module toward the processing chamber, among side surfaces of the load lock module.

In the processing system according to an exemplary embodiment of the disclosure, the utility module may further include a remote plasma generator that generates plasma, and supplies radicals in the generated plasma to each of the plurality of processing chambers included in the processing unit.

In the processing system according to an exemplary embodiment of the disclosure, each processing unit includes a third pipe through which the radicals generated by the remote plasma generator flow to be distributed to each of the plurality of processing chambers, and a length of the third pipe from the remote plasma generator to each of the plurality of processing chambers may be same among the plurality of processing chambers within the processing unit.

In the processing system according to an exemplary embodiment of the disclosure, each processing unit includes a load lock module disposed adjacent to each of the processing chambers, for the processing chamber, a width of the load lock module in a direction from the load lock module toward the processing chamber is narrower than a width of the processing chamber disposed adjacent to the load lock module, and the third pipe may be disposed in a gap formed by a side surface in an area not adjacent to the load lock module, in a side surface of the processing chamber at a side where the load lock module is disposed, and a side surface extending in a direction from the load lock module toward the processing chamber, among side surfaces of the load lock module.

In the processing system according to an exemplary embodiment of the disclosure, a number of the plurality of processing chambers included in each processing unit is an even number of two or more, and the utility module may be disposed between a n/2th processing chamber from above and a (n/2)+1th processing chamber from above when the number of the plurality of processing chambers included in the processing unit is n.

In the processing system according to an exemplary embodiment of the disclosure, an increase or decrease of the processing unit may be possible in units of the processing unit.

Hereinafter, an exemplary embodiment of a disclosed processing system will be described in detail with reference to drawings. The present exemplary embodiment does not limit the present disclosure. Exemplary embodiments may be properly combined with each other within a range in which the processing contents do not contradict each other.

[Configuration of Processing System 10]

FIG. 1 is a view illustrating an example of a processing system 10. FIG. 1 schematically illustrates the processing system 10 when viewed from the top side. The processing system 10 in the present exemplary embodiment, for example, as illustrated in FIG. 1, includes a loader module (LM) 11, a conveyance chamber 12, and a plurality of processing units 20-1 to 20-12. The processing system 10 is provided in, for example, a clean room. Hereinafter, the plurality of respective processing units 20-1 to 20-12 are described as processing units 20 when generically referred to without distinction. In FIG. 1, the processing system 10 including 12 processing units 20 is exemplified, but in the processing system 10, 11 or less processing units 20 may be provided, and 13 or more processing units 20 may be provided.

A plurality of ports are provided at the front side (the upper side in FIG. 1) of the LM 11, and a cassette in which unprocessed substrates W are accommodated by an operator or a cassette conveyance system is set in each of the ports. The unprocessed substrate W is an example of a processing target object. At the back side of the LM 11, the conveyance chamber 12 and the plurality of processing units 20 are disposed. In the example of FIG. 1, the plurality of processing units 20 are disposed in two rows in the lateral direction (for example, the x-axis direction illustrated in FIG. 1) with the conveyance chamber 12 interposed therebetween, and in each row, six processing units 20 are disposed in the lateral direction (for example, the y-axis direction illustrated in FIG. 1). A power supply unit 14 is disposed at the back side of the processing system 10.

A plurality of processing chambers are disposed in each processing unit 20. The power supply unit 14 supplies a high-frequency power with a predetermined frequency to each processing chamber.

A conveyance device 13 such as, for example, a movable robot arm is provided within the conveyance chamber 12. The conveyance device 13 takes an unprocessed substrate W out of the cassette set in the port of the LM 11. Then, the conveyance device 13 moves within the conveyance chamber 12 and conveys the substrate W taken out of the cassette to a processing chamber within any of the processing units 20. Then, the substrate W processed in the processing chamber is taken out of the processing chamber by the conveyance device 13, and returned to the cassette set in the port of the conveyance chamber 12.

[Configuration of Processing Unit 20]

FIG. 2 is a view illustrating an example of the processing unit 20. FIG. 3 is a view illustrating an example of the processing unit 20 when viewed from the direction A in FIG. 2. FIG. 4 is a view illustrating an example of the processing unit 20 when viewed from the direction B in FIG. 2.

The processing unit 20, for example, as illustrated in FIGS. 3 and 4, includes a plurality of processing chambers 22-1 to 22-4. Hereinafter, the plurality of respective processing chambers 22-1 to 22-4 are described as processing chambers 22 when generically referred to without distinction. The plurality of processing chambers 22-1 to 22-4 are disposed to overlap each other in the vertical direction (for example, the z-axis direction illustrated in FIGS. 3 and 4). In the processing unit 20 exemplified in FIGS. 3 and 4, four processing chambers 22-1 to 22-4 are disposed to overlap each other, but three or less processing chambers 22 may be disposed to overlap each other, or five or more processing chambers 22 may be disposed to overlap each other. In the present exemplary embodiment, the number of the processing chambers 22 included in the processing unit 20 is even.

Each processing chamber 22 includes a matching unit 220, a shower head 221 and a placing table 222. The matching unit 220 is a circuit that matches an output impedance of a high frequency power source with a load impedance. The shower head 221 supplies a processing gas supplied from a flow rate controller 31 described below into the processing chamber 22. A high-frequency power with a predetermined frequency supplied through the matching unit 220 is applied to the shower head 221. The shower head 221 serves as an upper electrode with respect to the placing table 222. On the top surface of the placing table 222, a substrate W as a processing target is placed. The placing table 222 serves as a lower electrode with respect to the shower head 221.

For example, as illustrated in FIGS. 2 and 4, load lock modules (LLMs) 21-1 to 21-4 are disposed adjacent to each other in the x-axis direction, in the processing chambers 22, respectively. Hereinafter, the plurality of respective LLMs 21-1 to 21-4 are described as LLMs 21 when generically referred to without distinction. Each of LLMs 21 includes a gate valve 210, a conveyance device 211 and a gate valve 212.

A utility module 30 is disposed between the processing chambers 22 adjacent in the vertical direction, for example, as illustrated in FIGS. 3 and 4. In the processing unit 20 of the present exemplary embodiment, n (n is an even number) processing chambers 22 are disposed to overlap each other in the vertical direction, and the utility module 30 is disposed between the n/2th processing chamber from above and the (n/2)+1th processing chamber from above. In the processing unit 20 as exemplified in FIGS. 3 and 4, four processing chambers 22 are disposed to overlap each other in the vertical direction, and the utility module 30 is disposed between the 2^{nd} processing chamber from above and the 3^{rd} processing chamber from above.

The utility module 30 includes the flow rate controller 31 and an exhaust valve 32. The flow rate controller 31 controls the flow rate of a processing gas supplied from a gas supply source 40 to a predetermined flow rate, and supplies the flow-rate-controlled processing gas to each processing chamber 22 through a pipe 230. The flow rate controller 31 may control the flow rate of a cleaning gas supplied from the gas supply source 40 to a predetermined flow rate, and supply the cleaning gas to each processing chamber 22 through the pipe 230. The pipe 230 is an example of a first pipe. The exhaust valve 32 is connected to each processing chamber 22 through a pipe 231, and is connected to an exhaust device 41 such as, for example, a turbo molecular pump through a pipe 232. Then, the exhaust valve 32 controls an exhaust amount of a gas exhausted from each processing chamber 22 by the exhaust device 41. The pipe 231 is an example of a second pipe. The exhaust valve 32 is an example of an exhaust controller.

In the present exemplary embodiment, the length of the pipe 230 from the flow rate controller 31 to each processing chamber 22 is the same among all processing chambers 22 within the processing unit 20. Accordingly, even in a case where the flow rate of a processing gas is controlled by one flow rate controller 31, a difference between the flow rates of the processing gas supplied to the respective processing chambers 22 may be reduced. Accordingly, it is possible to precisely control the flow rate of a processing gas supplied to the plurality of processing chambers 22 through one flow rate controller 31. Therefore, it becomes unnecessary to individually provide the flow rate controller 31 for each processing chamber 22, and thus a size reduction and a cost reduction for the processing unit 20 becomes possible.

In the present exemplary embodiment, the length of the pipe 231 from each processing chamber 22 to the exhaust valve 32 is the same among all processing chambers 22 within the processing unit 20. Accordingly, even in a case where the exhaust amount of a gas is controlled by one exhaust valve 32, a difference between exhaust amounts of the gas exhausted from the respective processing chambers 22 may be reduced. Accordingly, it is possible to precisely control the exhaust amount of a gas exhausted from the plurality of processing chambers 22 through one exhaust valve 32. Therefore, it becomes unnecessary to individually provide the exhaust valve 32 for each processing chamber 22, and thus a size reduction and a cost reduction for the processing unit 20 becomes possible.

In the present exemplary embodiment, the utility module 30, for example, as illustrated in FIGS. 3 and 4, is disposed at substantially the center of the processing unit 20 in the vertical direction. Accordingly, the length of each of the pipe 230 connected from the gas supply source 40 within the utility module 30 to each processing chamber 22, and the pipe 231 connected from each processing chamber 22 to the exhaust valve 32 within the utility module 30 may be shortened. Accordingly, the conductance of the pipe 230 and the pipe 231 may be increased, and thus the pressure control within each processing chamber 22 becomes easy. Then, a size reduction and a cost reduction for the processing unit 20 becomes possible.

For example, as illustrated in FIG. 2, in the direction from the LLM 21 toward the processing chamber 22 (for example, the x-axis direction in FIG. 2), the width L1 of the LLM 21 is narrower than the width L2 of the processing chamber 22 disposed adjacent to the LLM 21. Thus, when the processing chambers 22 of the adjacent processing units 20 are disposed to be adjacent to each other, for example, as illustrated in FIG. 2, a gap 23 is formed while surrounded by a side surface 223 in an area not adjacent to the LLM 21, in a side surface of the processing chamber 22 at the side where the LLM 21 is disposed, and a side surface 213 extending in a direction from the LLM 21 toward the processing chamber 22, among side surfaces of the LLM 21. In the gap 23, the pipe 230 and the pipe 231 are disposed.

When the substrate W is processed in the processing chamber 22, the gate valve 212 of the LLM 21 is opened, and the unprocessed substrate W is placed on the conveyance device 211 within the LLM 21 by the conveyance device 13. Then, the gate valve 212 is closed, and the inside of the LLM 21 is decompressed. Then, the gate valve 210 is opened, and the unprocessed substrate W is carried into the processing chamber 22 by the conveyance device 211 and placed on the placing table 222. Then, the gate valve 210 is closed again.

Then, a flow-rate-controlled processing gas is supplied to each processing chamber 22 by the flow rate controller 31. The processing gas supplied from the flow rate controller 31 is supplied from the shower head 221 into the processing chamber 22. Then, the exhaust amount of each processing chamber 22 is controlled by the exhaust valve 32, and the inside of the processing chamber 22 is controlled to a predetermined pressure. Then, a high-frequency power with a predetermined frequency is applied to the shower head 221 through the matching unit 220 so that plasma of a processing gas is generated within the processing chamber 22, and a predetermined processing such as, for example, etching or film-forming is performed on the substrate W placed on the placing table 222 by the generated plasma.

When the processing on the substrate W is completed, the gate valve 210 is opened, and the processed substrate W is carried out of the processing chamber 22 by the conveyance device 211. Then, the gate valve 210 is closed, and the pressure within the LLM 21 is returned to an atmospheric pressure. Then, the gate valve 212 is opened, and the processed substrate W is carried out of the LLM 21 by the conveyance device 13.

The processing system 10 of the present exemplary embodiment may be increased or decreased in units of processing units 20. For example, as illustrated in FIG. 5, in a processing system 10-2 including 12 processing units 20, the processing units 20 may be increased in the y-axis direction so that, for example, a processing system 10-1 including 14 processing units 20 may be configured. For example, as illustrated in FIG. 5, in the processing system 10-2 including 12 processing units 20, the processing units 20 may be decreased in the y-axis direction so that, for example, a processing system 10-3 including ten processing units 20 may be configured. In this manner, an increase or decrease is possible in units of processing units 20 in each of which the plurality of processing chambers 22 are disposed to overlap each other. Thus, the processing units 20 may be configured with a higher degree of freedom according to an area of an installation place or a required processing capability.

In the plurality of processing chambers 22 included in the processing unit 20, a processing gas supplied through the flow rate controller 31 is common, and thus the same processings are performed on the substrates W as processing targets. However, in processing chambers 22 included in separate processing units 20, different processings may be performed on the substrates W as processing targets. For example, in the processing system 10 exemplified in FIG. 1, a film-forming processing may be performed in the processing units 20-1 to 20-6, and an etching processing may be performed in the processing units 20-7 to 20-12. The processing system 10 may include an apparatus that performs a processing performed under an atmospheric pressure environment, such as, for example, a cleaning device, a heat treatment device, and a coater/developer.

As described above, an exemplary embodiment has been described. As is clear from the above description, the occupied area in the entire processing system 10 may be reduced in the processing system 10 of the present exemplary embodiment.

The disclosed technology is not limited to the exemplary embodiment described above, but many modifications may be made within the scope of the gist thereof.

For example, in the above exemplary embodiment, the processing chamber 22 included in each processing unit 20 generates plasma using the processing gas supplied through the flow rate controller 31 and the high-frequency power supplied through the matching unit 220, but the disclosed technology is not limited thereto. For example, as illustrated in FIG. 6, plasma may be generated by a remote plasma generator 33 provided within the utility module 30, and radicals in the generated plasma may be supplied to each processing chamber 22 through a pipe 233, and supplied into the processing chamber 22 from the shower head 221 within each processing chamber 22. The pipe 233 is an example of a third pipe.

In the processing unit 20 illustrated in FIG. 6 as well, the length of the pipe 233 from the remote plasma generator 33 to each processing chamber 22 is the same among all processing chambers 22 within the processing unit 20. Accordingly, even in a case where the plasma is generated by one remote plasma generator 33, a difference between the amounts of the radicals supplied to the respective processing chambers 22 may be reduced. Accordingly, it is possible to precisely control the amount of radicals supplied to the respective processing chambers 22 from one remote plasma generator 33. Therefore, it becomes unnecessary to individually generate plasma in each processing chamber 22, and thus a size reduction and a cost reduction for the processing unit 20 becomes possible.

For example, as illustrated in FIG. 7, one exhaust pump 34 may be provided within the utility module 30 to decompress each LLM 21, and a gas within each LLM 21 may be exhausted through a pipe 234. The gas exhausted from each LLM 21 by the exhaust pump 34 is sent to an exhaust gas processing device 42. In FIG. 7, a supply path of a processing gas to each processing chamber 22, and an exhaust path of a gas exhausted from each processing chamber 22 are omitted.

In the example of FIG. 7, since the plurality of LLMs 21 within the processing unit 20 may be decompressed by one exhaust pump 34, a size reduction and a cost reduction for the processing unit 20 becomes possible as compared to a case where the exhaust pump 34 is provided for each of the LLMs 21. In the processing unit 20 illustrated in FIG. 7 as well, the length of the pipe 234 from each LLM 21 to the exhaust pump 34 may be the same among all LLMs 21 within the processing unit 20. Accordingly, among the plurality of LLMs 21 within the processing unit 20, a difference in time until a pressure is reduced from an atmospheric pressure to a predetermined degree of vacuum may be reduced. Accordingly, the processing time may be shortened. In the processing unit 20 illustrated in FIG. 7 as well, the pipe 234 from each LLM 21 to the exhaust pump 34 may be disposed in the gap 23 surrounded by the side surface 213 of the LLM 21 and the side surface 223 of the processing chamber 22 as illustrated in FIG. 2.

In the processing unit 20 in the above exemplary embodiment, n (n is an even number) processing chambers 22 are disposed to overlap each other in the vertical direction, and the utility module 30 is disposed between the n/2th processing chamber 22 from above and the (n/2)+1th processing chamber 22 from above, but the disclosed technology is not limited thereto. For example, the utility module 30 may be disposed above the uppermost processing chamber 22, below the lowermost processing chamber 22, or between any two processing chambers 22 adjacent in the vertical direction. However, even in this case, the length of the pipe 230 connected from the flow rate controller 31 within the utility module 30 to each processing chamber 22, or the pipe 231 connected from each processing chamber 22 to the exhaust valve 32 may be the same among all processing chambers 22 within the processing unit 20.

Although the present disclosure has been described using the exemplary embodiment, but the technical scope of the present disclosure is not limited to the scope described in the exemplary embodiment. It is obvious to a person skilled in the art that various modifications or improvements may be made for the above exemplary embodiment. It is apparent from the description of the scope of claims that forms with such modifications or improvements may also be included in the technical scope of the present disclosure.

### DESCRIPTION OF SYMBOLS

| | | | |
|---|---|---|---|
| 10: | processing system | 11: | LM |
| 12: | conveyance chamber | 13: | conveyance device |
| 14: | power supply unit | 20: | processing unit |
| 21: | LLM | 210: | gate valve |
| 211: | conveyance device | 212: | gate valve |
| 22: | processing chamber | 220: | matching unit |
| 221: | shower head | 222: | placing table |
| 23: | gap | 230: | pipe |
| 231: | pipe | 232: | pipe |
| 233: | pipe | 234: | pipe |
| 30: | utility module | 31: | flow rate controller |
| 32: | exhaust valve | 33: | remote plasma generator |
| 34: | exhaust pump | 40: | gas supply source |
| 41: | exhaust device | 42: | exhaust gas processing device |

1. A processing system comprising:
at least one processing unit,
wherein each processing unit includes a plurality of processing chambers configured to process a processing target object using a supplied processing gas, and a utility module including a flow rate controller configured to control a flow rate of the processing gas supplied to each of the plurality of processing chambers,
the plurality of processing chambers are disposed to overlap each other in a vertical direction, and
the utility module is disposed between two processing chambers adjacent in the vertical direction, among the plurality of processing chambers.

2. The processing system of claim 1, wherein each processing unit includes a first pipe through which the processing gas flows to be distributed from the flow rate controller to each of the plurality of processing chambers, and
a length of the first pipe from the flow rate controller to each of the plurality of processing chambers is same among the plurality of processing chambers within the processing unit.

3. The processing system of claim 2, wherein each processing unit includes a load lock module disposed adjacent to each of the processing chambers, for the processing chamber,
a width of the load lock module in a direction from the load lock module toward the processing chamber is narrower than a width of the processing chamber disposed adjacent to the load lock module, and
the first pipe is disposed in a gap formed by a side surface in an area not adjacent to the load lock module, in a side surface of the processing chamber at a side where the load lock module is disposed, and a side surface extending in a direction from the load lock module toward the processing chamber, among side surfaces of the load lock module.

4. The processing system of claim 1, wherein the utility module further includes an exhaust controller configured to control an exhaust amount of a gas exhausted from each of the plurality of processing chambers included in the processing unit.

5. The processing system of claim 4, wherein each processing unit includes a second pipe through which the gas exhausted from each of the plurality of processing chambers flows, and
a length of the second pipe from each of the plurality of processing chambers to the exhaust controller is same among the plurality of processing chambers within the processing unit.

6. The processing system of claim 5, wherein each processing unit includes a load lock module disposed adjacent to each of the processing chambers, for the processing chamber,
a width of the load lock module in a direction from the load lock module toward the processing chamber is narrower than a width of the processing chamber disposed adjacent to the load lock module, and
the second pipe is disposed in a gap formed by a side surface in an area not adjacent to the load lock module, in a side surface of the processing chamber at a side where the load lock module is disposed, and a side surface extending in a direction from the load lock module toward the processing chamber, among side surfaces of the load lock module.

7. The processing system of claim 1, wherein the utility module further includes a remote plasma generator that generates plasma, and supplies radicals in the generated plasma to each of the plurality of processing chambers included in the processing unit.

8. The processing system of claim 7, wherein each processing unit includes a third pipe through which the radicals generated by the remote plasma generator flow to be distributed to each of the plurality of processing chambers, and
a length of the third pipe from each of the plurality of processing chambers to the remote plasma generator is same among the plurality of processing chambers within the processing unit.

9. The processing system of claim 8, wherein each processing unit includes a load lock module disposed adjacent to each of the processing chambers, for the processing chamber,
a width of the load lock module in a direction from the load lock module toward the processing chamber is narrower than a width of the processing chamber disposed adjacent to the load lock module, and
the third pipe is disposed in a gap formed by a side surface in an area not adjacent to the load lock module, in a side surface of the processing chamber at a side where the load lock module is disposed, and a side surface extending in a direction from the load lock module toward the processing chamber, among side surfaces of the load lock module.

10. The processing system of claim 1, wherein a number of the plurality of processing chambers included in each processing unit is an even number of two or more, and
the utility module is disposed between a n/2th processing chamber from above and a (n/2)+1th processing chamber from above when the number of the plurality of processing chambers included in the processing unit is n.

11. The processing system of claim 1, wherein an increase or decrease of the processing units is possible in units of the processing unit.
